(19) United States
(12) Patent Application Publication
(10) Pub. No.: US 2025/0169053 A1
(43) Pub. Date: May 22, 2025

(54) SEMICONDUCTOR DEVICE AND METHOD FOR MANUFACTURING THE SAME

(71) Applicant: SK hynix Inc., Gyeonggi-do (KR)

(72) Inventor: Nam Jae LEE, Gyeonggi-do (KR)

(21) Appl. No.: 18/928,209

(22) Filed: Oct. 28, 2024

(30) Foreign Application Priority Data
Nov. 20, 2023 (KR) 10-2023-0161547

(51) Int. Cl. H10B 12/00; H01L 23/00; H01L 25/065; H01L 25/18; H10B 80/00

(52) U.S. Cl. CPC H10B 12/20; H01L 24/08; H01L 25/0657; H01L 25/18; H10B 80/00; H01L 2224/08145; H01L 2924/1431; H01L 2924/1436

(57) ABSTRACT

A semiconductor device includes a bit line formed to extend in a first direction, a word line formed to extend in a second direction perpendicular to the first direction, and at least one thyristor formed to contact the bit line and to extend in a third direction perpendicular to each of the first direction and the second direction. The thyristor includes a first region, a second region disposed below the first region, a third region disposed below the second region, and a fourth region disposed below the third region and connected to the bit line. The word line surrounds the third region.

### CROSS-REFERENCE TO RELATED APPLICATION

This patent application claims the priority and benefits of Korean patent application No. 10-2023-0161547, filed on Nov. 20, 2023, the disclosure of which is incorporated herein by reference in its entirety.

### TECHNICAL FIELD

The technology and embodiments of the present disclosure generally relate to a semiconductor device, and more particularly to a semiconductor device including vertical memory cells, and a method for manufacturing the same.

### BACKGROUND

As miniaturization and higher degree of integration of semiconductor devices have emerged as major challenges, various technical issues have been encountered.

For example, as the area of a unit cell of a semiconductor device decreases, it becomes difficult to secure sufficient capacitance. Accordingly, operation characteristics of the semiconductor device can be improved by organizing memory cells included in the semiconductor device vertically.

### SUMMARY

In accordance with an embodiment of the present disclosure, a semiconductor device may include a bit line extending in a first direction, a word line extending in a second direction perpendicular to the first direction, and at least one thyristor contacting the bit line and extending in a third direction perpendicular to each of the first direction and the second direction. The thyristor includes a first region, a second region disposed below the first region, a third region disposed below the second region, and a fourth region disposed below the third region and connected to the bit line.

In some embodiments, the first region and the third region may be regions containing impurities of a first conductivity type, the second region and the fourth region may be regions containing impurities of a second conductivity type, and the word line surrounds at least a portion of the third region.

In some embodiments, the word line may include, for example, polysilicon.

In some embodiments, the semiconductor device may further include a gate insulation layer disposed between the word line and the third region.

In some embodiments, the gate insulation layer may include silicon oxide.

In some embodiments, the first region may be disposed over a second region included in a first thyristor and a second thyristor.

In some embodiments, the semiconductor device may further include a plurality of thyristors arranged in a zigzag pattern with respect to the second direction and spaced apart from each other by a preset distance.

In some embodiments, the plurality of thyristors may be arranged in two lines, and the word line may be formed to surround at least a portion of each of the plurality of thyristors.

In some embodiments, the word line may further include a metal silicide.

In some embodiments, the fourth region may further include a metal silicide.

In accordance with an embodiment of the present disclosure, a semiconductor device may include a memory cell array; and a peripheral circuit region disposed below the memory cell array. The memory cell array includes a bit line formed in a first direction, a word line formed to extend in a second direction perpendicular to the first direction, and at least one thyristor contacting the bit line and extending in a third direction perpendicular to each of the first direction and the second direction. The peripheral circuit region may include a control circuit configured to provide a control signal to the memory cell array, and a connection structure connected to the bit line.

In some other embodiments, the thyristor may include a first region extending in the first direction, a second region disposed below the first region, a third region disposed below the second region, and a fourth region disposed below the third region and connected to the bit line.

In some other embodiments, the first region and the third region including impurities of a first conductivity type, and the second region and the fourth region including impurities of a second conductivity type.

In some other embodiments, the word line may be formed to surround the third region.

In some other embodiments, the semiconductor device may further include a gate insulation layer disposed between the word line and the third region.

In some other embodiments, the word line includes polysilicon, and the gate insulation layer includes silicon oxide.

In accordance with another embodiment of the present disclosure, a method for manufacturing a semiconductor device may include forming a conductive material layer over an upper substrate layer; forming a pre-word line and at least one first opening by etching the conductive material layer; forming a gate insulation layer by oxidizing a portion of the pre-word line exposed through the first opening; forming a second region, a third region, and a fourth region within the first opening through an epitaxial process; forming a word line surrounding the third region by forming at least one second opening within the pre-word line; forming a bit line connected to the fourth region; and forming a first region by back-grinding the upper substrate layer and performing impurity doping on the back-ground upper substrate layer.

In some other embodiments, the method for manufacturing the semiconductor device may further include forming a metal silicide layer within the word line; and forming the metal silicide layer within the fourth region.

In some other embodiments, the method for manufacturing the semiconductor device may further include: forming a first bonding layer over the bit line; forming a peripheral circuit region that includes a lower substrate layer and a second bonding layer; and connecting the first bonding layer and the second bonding layer to each other.

In accordance with another embodiment of the present disclosure, a semiconductor device may include at least two bit lines spaced apart from each other and extending parallel to each other in a first horizontal direction, at least two thyristors, each thyristor extending vertically and being connected at a first end thereof to one of the at least two bit lines, a word line extending in a second direction perpendicular to the first horizontal direction and surrounding a portion of a sidewall surface of the at least two thyristors, wherein the at least two thyristors are aligned in a diagonal direction.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a plan view illustrating a memory cell array according to some embodiments of the present disclosure.

FIG. 2 is a cross-sectional view illustrating the memory cell array taken along a first cutting line of FIG. 1 according to some embodiments of the present disclosure.

FIG. 3 is a cross-sectional view illustrating the memory cell array taken along a second cutting line of FIG. 1 according to some embodiments of the present disclosure.

FIG. 4 is a cross-sectional view illustrating the memory cell array taken along a third cutting line of FIG. 1 according to some embodiments of the present disclosure.

FIG. 5 is a cross-sectional view illustrating a semiconductor device according to some embodiments of the present disclosure.

FIG. 6 is a perspective view illustrating a configuration of a unit memory cell according to some embodiments of the present disclosure.

FIGS. 7 to 17 are cross-sectional views illustrating a method for manufacturing a semiconductor device according to some embodiments of the present disclosure.

### DETAILED DESCRIPTION

The present disclosure provides embodiments and examples of a semiconductor device including vertical memory cells, and a method for manufacturing the same that may be used in configurations to substantially address one or more technical or engineering issues and to mitigate limitations or disadvantages encountered in some other semiconductor device designs. Some embodiments of the present disclosure relate to a vertical memory device with a higher degree of integration and a method for manufacturing the same. In recognition of the issues above, the semiconductor device according to some embodiments of the present disclosure may include thyristors instead of capacitors. The semiconductor device can implement a highly integrated memory device including vertical thyristors, and can simplify a fabrication process thereof.

Reference will now be made in detail to the embodiments of the present disclosure, examples of which are illustrated in the accompanying drawings. Wherever possible, the same reference numbers will be used throughout the drawings to refer to the same or like parts. While the present disclosure is susceptible to various modifications and alternative forms, specific embodiments thereof are shown by way of example in the drawings. However, this disclosure should not be construed as being limited to the embodiments set forth herein.

Hereinafter, various embodiments will be described with reference to the accompanying drawings. However, it should be understood that the present disclosure is not limited to specific embodiments, but includes various modifications, equivalents and/or alternatives of the embodiments. The embodiments of the present disclosure may provide a variety of effects capable of being directly or indirectly recognized.

In the following description, a detailed description of related known configurations or functions incorporated herein will be omitted to avoid obscuring the subject matter.

The terminology used herein is for the purpose of describing particular embodiments only and is not intended to be limiting of the present disclosure. As used herein, the singular forms are intended to include the plural forms as well, unless the context clearly indicates otherwise. It will be further understood that the terms “comprises”, “includes”, “including”, and/or “comprising,” when used in this specification, specify the presence of stated constituent elements, steps, operations, and/or components, but do not preclude the presence or addition of one or more other constituent elements, steps, operations, and/or components thereof. The term “and/or” may include a combination of a plurality of items or any one of a plurality of items.

The drawings may not be necessarily drawn to scale, and in some examples, proportions of at least some of structures in the drawings may be exaggerated to clearly show features of the embodiments. When a multilayer structure having two or more layers is disclosed in the drawings or detailed description, the relative positional relationship or arrangement order of the layers reflects a specific embodiment only and the scope or spirit of the present disclosure is not limited thereto, and it should be noted that the relative positional relationship or arrangement order of the layers may also be changed as necessary.

Various embodiments of the present disclosure relate to a vertical memory device with a higher degree of integration, and a method for manufacturing the same.

It is to be understood that both the foregoing general description and the following detailed description of the present disclosure are illustrative and descriptive and are intended to provide further description of the embodiments as claimed.

Hereinafter, a semiconductor device and a method for manufacturing the same according to some embodiments of the present disclosure will be described in detail with reference to the drawings.

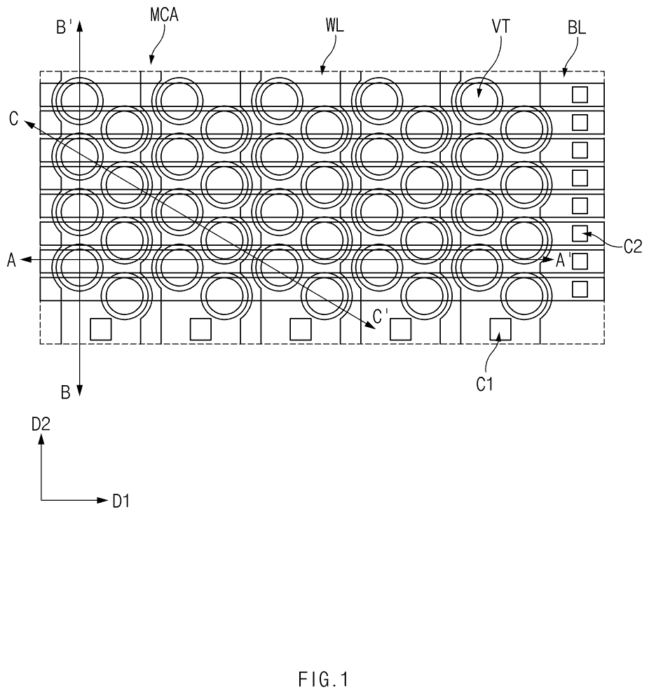

FIG. 1 is a plan view illustrating a memory cell array (MCA) according to some embodiments of the present disclosure.

Referring to FIG. 1, a semiconductor device may include a memory cell array (MCA).

The semiconductor device may be implemented as a thyristor-based random access memory (RAM) that includes one or more thyristors instead of one or more capacitors to minimize volatility and power consumption as well as to improve circuit integration.

The thyristor included in the semiconductor device may be a thyristor of a PNPN-based thyristor, and may enable the thyristor to be implemented as a vertical thyristor structure. The thyristor may thus minimize the area of the memory cell.

The memory cell array (MCA) may be a region located above a peripheral circuit region (not shown) included in the semiconductor device, and may include a plurality of thyristors (VTs).

Each unit memory cell included in the memory cell array (MCA) may include a single thyristor (VT).

The thyristor (VT) may have a PNPN structure including a silicon material with P-type impurities and a silicon material with N-type impurities repeatedly stacked over each other.

The unit memory cell may store data using the high-resistance characteristics and low-resistance characteristics of the thyristor (VT).

A bit line BL extending in a first direction (i.e., D1 direction) may be disposed at a lower portion of each thyristor (VT). Each bit line (BL) may be connected to a plurality of thyristors (VTs) arranged in the same direction (e.g., ‘D1’ direction or ‘ROW’ direction).

In addition, a word line (WL) may be arranged to surround at least a portion of a side surface of the thyristor (VT).

The thyristors (VTs) included in the memory cell array (MCA) may be arranged in a zig-zag pattern with respect to the second direction (i.e., D2 direction).

The thyristors (VTs) may be spaced apart from each other by a preset distance. Each word line (WL) may be arranged to surround the side surfaces of a plurality of thyristors (VTs) arranged in two lines.

Two thyristors (VTs) surrounded by one word line (WL) and adjacent to each other may be arranged in a diagonal direction.

Since two adjacent thyristors are diagonally arranged in the memory cell array (MCA), the degree of integration of the memory cell array (MCA) is increased.

In addition, since two adjacent thyristors (VTs) are arranged in the diagonal direction, each thyristor (VT) may individually perform a read operation and a write operation.

The word line (WL) may include, for example, polysilicon. In some embodiments, the word line (WL) may further include a metal silicide such as nickel silicide.

A gate insulation layer may be formed between the word line (WL) and the thyristor (VT) and the word line (WL) may also be referred to as a gate.

The word line (WL) may be connected to a control circuit through a first contact (C1). For example, the control circuit may provide a control voltage to the word line (WL). More specifically, the control circuit may include a word line driver. The word line driver may be disposed in a peripheral circuit region (not shown) located below the memory cell array (MCA).

The first contact (C1) may be a conductive through silicon via (TSV) structure. For example, the first contact (C1) may be a via containing a metal material.

The bit line (BL) may be connected to one side of the thyristor (VT) and may be a layer containing a conductive material. In some embodiments, the bit line (BL) may include a plurality of layers, and each layer may include tungsten, tungsten nitride, tungsten silicide, or the like.

The bit line (BL) may be electrically connected to a P-type impurity layer included in the thyristor (VT). The bit line (BL) and the thyristor (VT) may be connected to each other through a bit line contact (not shown) containing a conductive material.

A second contact (C2) may be a conductive TSV structure. For example, the second contact (C2) may be a via containing a metal material.

The bit line (BL) may be connected to the control circuit through the second contact (C2). For example, the control circuit may include a sense amplifier (sense-amp). The sense amplifier may be disposed in a peripheral circuit region (not shown) located below the memory cell array (MCA).

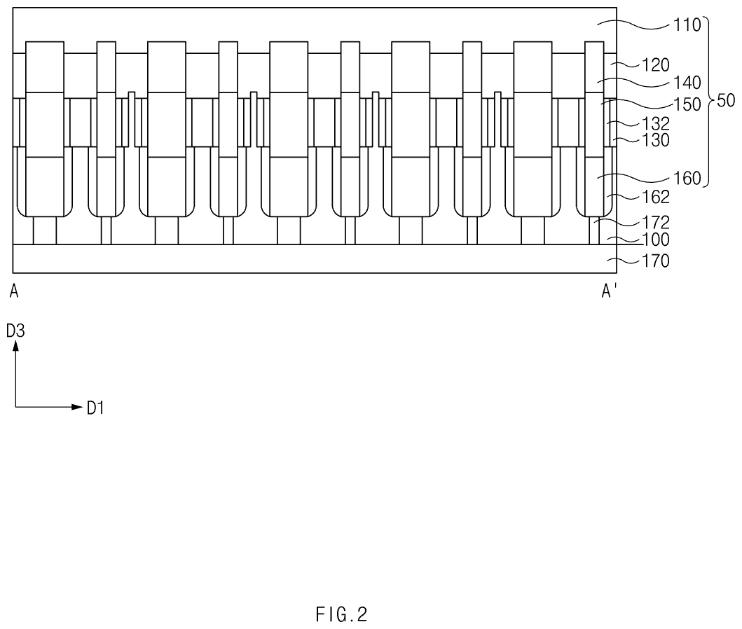

FIG. 2 is a cross-sectional view illustrating the memory cell array (MCA) taken along a first cutting line A-A′ of FIG. 1 according to some embodiments of the present disclosure.

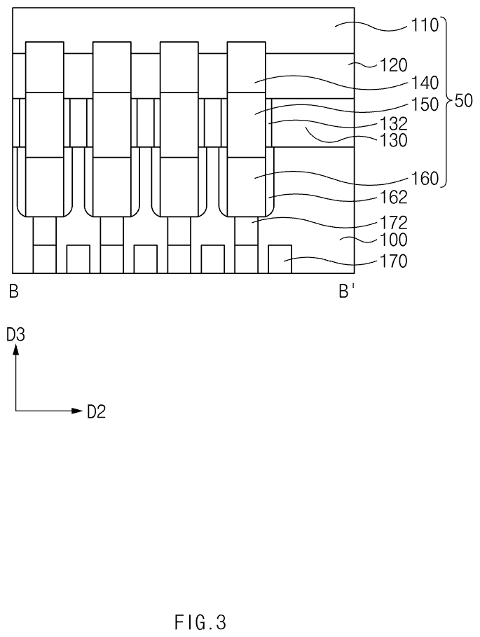

FIG. 3 is a cross-sectional view illustrating the memory cell array (MCA) taken along a second cutting line B-B′ of FIG. 1 according to some embodiments of the present disclosure.

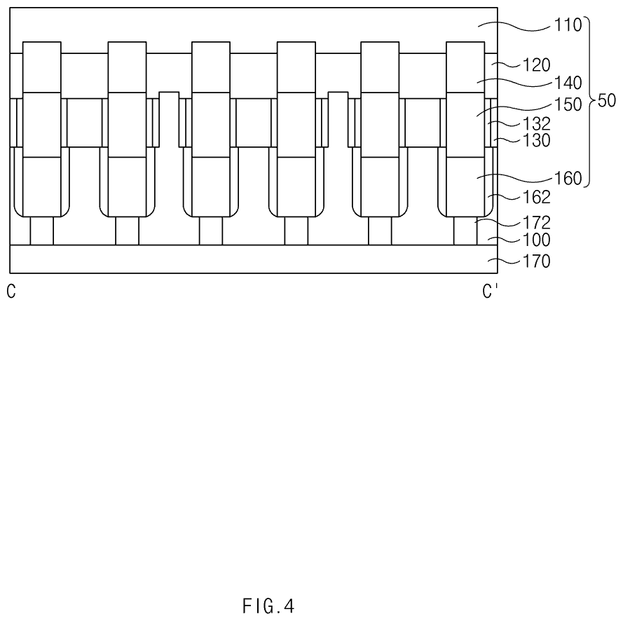

FIG. 4 is a cross-sectional view illustrating the memory cell array (MCA) taken along a third cutting line C-C′ of FIG. 1 according to some embodiments of the present disclosure.

The positional relationships among the thyristor 50, the word line 130, and the bit line 170 included in the memory cell array (MCA) will hereinafter be described with reference to FIGS. 2 to 4.

The cross-sectional view of FIG. 2 is a cross-sectional view of the memory cell array (MCA) taken along the cutting line A-A′ passing through the center of the bit line 170 extending in the first direction (i.e., D1 direction). FIG. 2 shows a cross-sectional view of thyristors 50 arranged in a zigzag pattern.

The cross-sectional view of FIG. 3 is a cross-sectional view of the memory cell array (MCA) taken along the cutting line B-B′ that extends in the second direction (i.e., D2 direction) while passing through the centers of the thyristors 50. FIG. 3 shows a cross-sectional view of thyristors 50 consecutively arranged in the second direction (i.e., D2 direction).

The cross-sectional view of FIG. 4 is a cross-sectional view of the memory cell array (MCA) taken along the cutting line C-C′ that extends diagonally in the first direction (i.e., D1 direction) and the second direction (i.e., D2 direction). The cutting line C-C′ passes through the center of a plurality of thyristors 50.

Each thyristor 50 may include a first region 110, a second region 140, a third region 150, and a fourth region 160 stacked in the vertical direction (i.e., D3 direction).

Each of the first region 110 and the third region 150 may be a silicon region doped with impurities of a first conductivity type. Each of the second region 140 and the fourth region 160 may be a silicon region doped with impurities of a second conductivity type. The first conductivity type impurities may be P-type impurities, and the second conductivity type impurities may be N-type impurities.

In some embodiments, the concentration of the impurities in the first region 110 may be higher than the concentration of the impurities in the third region 150.

In addition, the concentration of the impurities in the second region 140 may be equal to the concentration of the impurities in the fourth region 160.

The first region 110 may be formed by back-grinding a silicon substrate (i.e., an upper substrate layer) and then performing ion implantation on the resultant silicon substrate.

The second region 140, the third region 150, and the fourth region 160 may be regions grown by forming an opening through an etching process and then performing an epitaxial process in the formed opening.

Two adjacent thyristors 50 may share one word line 130.

The word line 130 may be arranged to surround at least partially the sidewall of the third region 150 included in the thyristor 50. In some embodiments, the third region 150 may be a storage layer of the thyristor 50.

The word line 130 in the third direction (D3 direction) may have a shorter length than the third region 150 in the third direction (D3 direction).

The word line 130 may include, for example, polysilicon. In some embodiments, the word line 130 may include a metal silicide such as nickel silicide (NiSi). In some embodiments the word line 130 may include both polysilicon and metal silicide. In some embodiments, sections of the word line may comprise polysilicon and other sections may comprise a metal silicide. Employing metal silicide for the word line 130 may improve the resistance characteristics of the word line substantially.

A gate insulation layer 132 may be formed between the thyristor 50 and the word line 130. The thyristor 50 and the word line 130 may be electrically isolated from each other by the gate insulation layer 132.

For example, the gate insulation layer 132 may be formed by oxidizing polysilicon. More specifically, the gate insulation layer 132 may be formed by selectively oxidizing polysilicon located within an opening formed through a photolithography process.

The fourth region 160 of the thyristor 50 may contact a bit line contact 172. The fourth region 160 may include a metal silicide in a region formed to contact the bit line contact 172. Since the fourth region 160 includes metal silicide, contact resistance between the bit line contact 172 and the fourth region 160 may be reduced.

The bit line contact 172 may be connected to the bit line 170. The bit line contact 172 may be a vertical via contact that includes a conductive material and extends in the vertical direction (i.e., D3 direction).

The memory cell array (MCA) may further include a plurality of layers for electrically insulating the thyristor 50 and the bit line 170.

For example, the memory cell array (MCA) may include a first isolation layer 100 that is disposed not only between the bit line contacts 172 but also between the thyristors 50.

The first isolation layer 100 may include an insulative material such as silicon oxide, and may be formed through deposition of silicon oxide and a chemical mechanical planarization (CMP) process.

The second isolation layer 120 may be a region disposed between the second regions 140 included in the thyristor 50, and may include an insulative material such as silicon oxide. The second isolation layer 120 may be formed through deposition of silicon oxide and an etching process.

The capping layer 162 may be a layer for insulating the fourth region 160 of the thyristor 50, and may include an insulative material such as silicon oxide. The capping layer 162 may be formed through deposition of silicon oxide and an etching process.

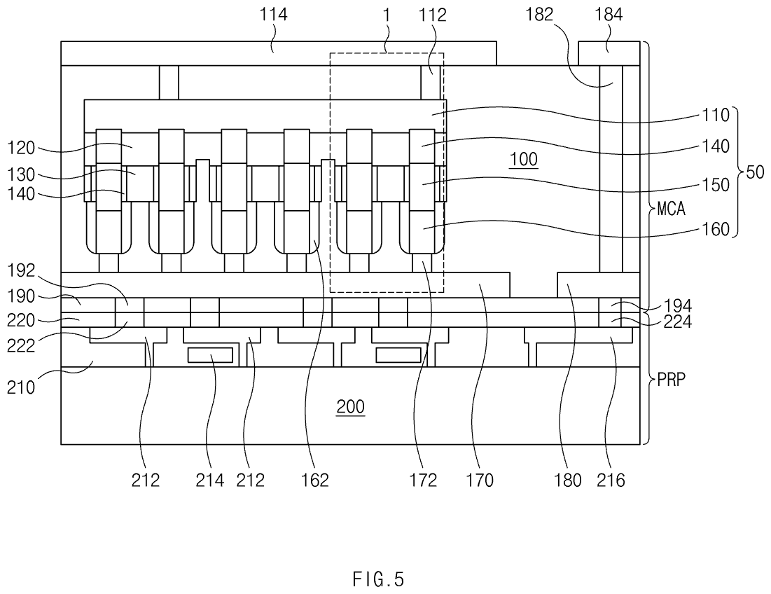

FIG. 5 is a cross-sectional view illustrating a semiconductor device according to some embodiments of the present disclosure.

A detailed cross-sectional view of a semiconductor device including a memory cell array (MCA) and a peripheral circuit region (PRP) is illustrated in FIG. 5.

The cross-sectional view of FIG. 5 is a cross-sectional view of the semiconductor device including the memory cell array (MCA) shown in FIG. 4.

More specifically, the cross-sectional view of FIG. 5 is a cross-sectional view in which the cross-section of FIG. 4 is expanded to the entire semiconductor device.

Redundant descriptions among the contents previously described with reference to FIGS. 1 to 4 will herein be omitted.

Referring to FIG. 5, a peripheral circuit region (PRP) may be disposed below the memory cell array (MCA).

The memory cell array (MCA) and the peripheral circuit region (PRP) may be connected to each other by wafer bonding.

The memory cell array (MCA) may include a plurality of thyristors 50.

The first region 110 included in the thyristor 50 may be connected to a first upper interconnect layer 114 through one or more upper interconnect contacts 112.

The first region 110 may be commonly included in the plurality of thyristors 50 included in the memory cell array (MCA).

The first region 110 may be disposed over the second region 140 included in any thyristor 50 included in the memory cell array (MCA).

Each of the plurality of the upper interconnect contacts 112 may be a vertical via contact formed in the first isolation layer 100. The upper interconnect contacts 112 may include a conductive material, and may extend in a vertical direction.

The first upper interconnect layer 114 may include a conductive material. The first upper interconnect layer 114 may be connected to the first region 110, and may operate as a source line.

A metal line 180 located on the same layer as the bit line 170 in the vertical direction may be a region connected to a second upper interconnect layer 184 through a vertical via 182. The metal line 180, the vertical via 182, and the second upper interconnect layer 184 may include a conductive material, and may electrically connect elements (e.g., thyristors 50) included in the memory cell array (MCA) to elements (e.g., a control circuit 214) of the memory cell array (MCA). The metal line 180 and the bit line 170 may be formed through an interconnect process (also called a wiring process).

A first bonding layer 190 located below the bit line 170 and the metal line 180 may include a first bonding pad 192 and a second bonding pad 194.

The first bonding layer 190 may contain an insulative material such as silicon oxide, and may contain the same material as the second bonding layer 220.

Each of the first bonding pad 192 and the second bonding pad 194 may include a conductive material. For example, each of the first bonding pad 192 and the second bonding pad 194 may be implemented as a bonding metal pad including a metal material.

The peripheral circuit region (PRP) may include a lower substrate layer 200, a third isolation layer 210, and a second bonding layer 220.

The lower substrate layer 200 may be a semiconductor substrate layer including a silicon substrate. In some embodiments, the lower substrate layer 200 may include a material suitable for semiconductor processing.

By way of example, the lower substrate layer 200 may include silicon, monocrystalline silicon, polysilicon, amorphous silicon, silicon germanium, monocrystalline silicon germanium, polycrystalline silicon germanium, carbon doped silicon, or combinations thereof.

In addition, the lower substrate layer 200 may also include other semiconductor materials such as germanium. The lower substrate layer 200 may include a group III/V semiconductor substrate, for example, a compound semiconductor substrate such as GaAs.

The third isolation layer 210 may include a first connection structure 212, a control circuit 214, and a second connection structure 216, and may be a layer including an insulative material such as silicon oxide.

The first connection structure 212, the control circuit 214, and the second connection structure 216 located inside the third isolation layer 210 may be electrically isolated from each other by the insulative material making the rest of the third isolation layer 210.

The first connection structure 212 may include at least one metal interconnect, and may include a multi-level metal interconnect including a plurality of vias and a plurality of metal interconnects.

The first connection structure 212 may be connected to a third bonding pad 222 included in the second bonding layer 220, and may be electrically connected to constituent elements (e.g., the bit line 170, etc.) included in the memory cell array (MCA) through the third bonding pad 222.

The control circuit 214 may include at least one transistor. The transistor may be a planar channel transistor. The transistor structure included in the control circuit 214 may include, for example, a recess channel transistor, a buried gate transistor, or a fin field effect transistor (FinFET), in addition to the planar channel transistor.

The control circuit 214 may determine whether to provide a control signal to the bit line 170, the word line 130, or the first upper interconnect 114 (i.e., a source line) included in the memory cell array (MCA).

The second connection structure 216 may include at least one metal interconnect, and may include a multi-level metal interconnect including a plurality of vias and a plurality of metal interconnects. The second connection structure 216 may be connected to a fourth bonding pad 224, and may be connected to the metal line 180 and the vertical via 182 through the fourth bonding pad 224.

The second bonding layer 220 is disposed over the third isolation layer 210. The second bonding layer 220 may cover the third isolation layer 210 and may be in contact with the third isolation layer 210. The second bonding layer 220 may include a third bonding pad 222 and a fourth bonding pad 224. The third and fourth bonding pads 222 and 224 may be spaced apart from each other.

The second bonding layer 220 may be a layer containing an insulative material such as silicon oxide. The second bonding layer 220 may contain the same material as the first bonding layer 190.

The third and fourth bonding pads 222 and 224 may include a conductive material. For example, each of the third and fourth bonding pads 222 and 224 may be a bonding metal pad including a metal material.

FIG. 5 shows an embodiment in which the peripheral circuit region (PRP) is disposed below the memory cell array (MCA). However, in some embodiments, the semiconductor device may have a peri-over cell (POC) structure in which the peripheral circuit region (PRP) is located above the memory cell array (MCA).

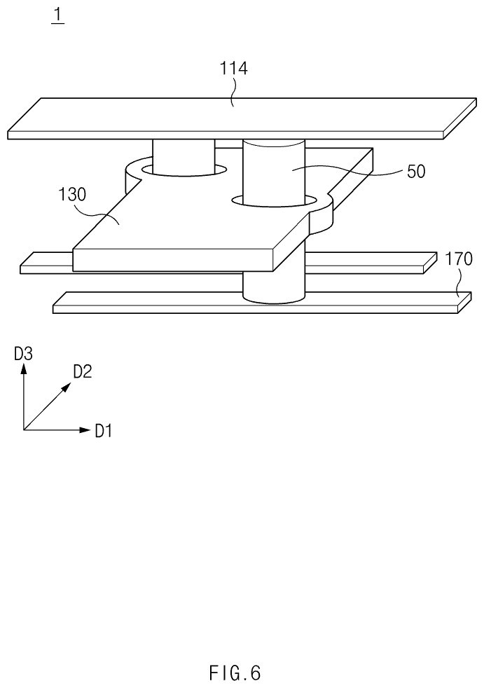

FIG. 6 is a perspective view illustrating a configuration of a unit memory cell according to some embodiments of the present disclosure.

A detailed structure of a partial region 1 of the memory cell array (MCA) shown in FIG. 5 will hereinafter be described with reference to FIG. 6.

The partial region 1 (see FIG. 5) of the memory cell array (MCA) shown in FIG. 5 may be a region containing two adjacent thyristors 50.

As can be seen from FIG. 6, the positional relationship among the thyristor 50, the word line 130, the bit line 170, and the first upper interconnect layer 114 (i.e., a source line) is shown in detail.

Referring to FIG. 6, the bit line 170 and the first upper interconnect layer 114 may extend in the first direction (i.e., D1 direction). The word line 130 may extend in the second direction (i.e., D2 direction) perpendicular to the first direction (i.e., D1 direction). In addition, the word line 130 may be formed to surround the sidewall of the thyristor 50.

The word line 130 and the thyristor 50 may be spaced apart from each other by the thickness of the gate insulation layer 132.

The thyristor 50 may be connected to the bit line 170 through a bit line contact, and may be connected to the first upper interconnect layer 114 through an upper interconnect contact, without being limited thereto. However, for convenience of description, the bit line contact and the upper interconnect layer are omitted from FIG. 6.

The first upper interconnect layer 114 may be commonly connected to the plurality of thyristors 50. The first upper interconnect layer 114 may operate as a source line for the plurality of thyristors 50.

The bit line 170 may be connected to each of the plurality of thyristors 50. Since the bit line 170 is connected to each of the thyristors 50, the thyristors 50 can operate as individual memory elements.

Since the semiconductor device according to some embodiments of the present disclosure includes the thyristors 50 instead of capacitors, the semiconductor device need not be refreshed and may have a structure in which each memory cell includes one transistor.

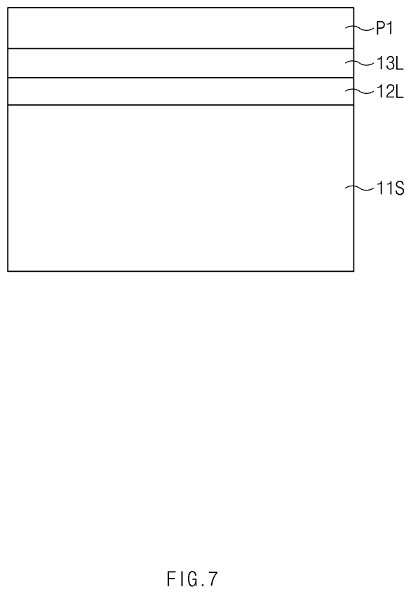

FIGS. 7 to 17 are cross-sectional views illustrating a method for manufacturing the semiconductor device according to some embodiments of the present disclosure.

Referring to FIG. 7, an insulative material layer 12L, a conductive material layer 13L, and a first protective layer P1 may be stacked over each other over an upper substrate layer 11S.

The upper substrate layer 11S is made of a material suitable for semiconductor processing. For example, the upper substrate layer 11S may include a silicon substrate. The upper substrate layer 11S may include silicon, monocrystalline silicon, polysilicon, amorphous silicon, silicon germanium, monocrystalline silicon germanium, polycrystalline silicon germanium, carbon doped silicon, combinations thereof, or multilayers thereof.

The upper substrate layer 11S may also include other semiconductor materials such as germanium. The upper substrate layer 11S may include a group III/V semiconductor substrate, for example, a compound semiconductor substrate such as GaAs. The upper substrate layer 11S may be a substrate from which at least a portion of the upper substrate layer 11S is removed by subsequent back grinding and additional impurity doping is then performed.

The insulative material layer 12L containing an insulative material such as silicon oxide may be formed over the upper substrate layer 11S. The insulative material layer 12L may electrically isolate the upper substrate layer 11S and the conductive material layer 13L from each other.

The conductive material layer 13L may be formed over the insulative material layer 12L.

The conductive material layer 13L may have a lower height than the third region 15 to be formed later.

The conductive material layer 13L may include, for example, polysilicon. In some embodiments, the conductive material layer 13L may include metal, metal nitride, metal silicide, or a combination thereof.

Hereinafter, the following description will be made based on the conductive material layer 13L containing polysilicon.

A first protective layer P1 may be formed over the conductive material layer 13L. The first protective layer P1 may include silicon nitride.

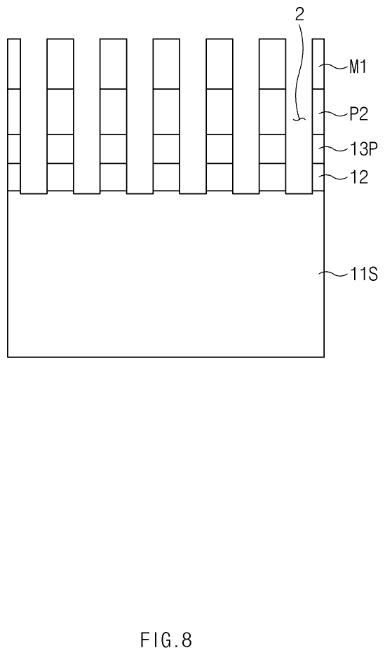

Referring to FIG. 8, a first mask layer M1 may be formed over the first protective layer P1, and a plurality of first openings 2 may be formed using the first mask layer M1.

When the first openings 2 are formed, the second isolation layer 12 may be disposed over the upper substrate layer 11S, and a pre-word line 13P may be disposed over the second isolation layer 12. A second protective layer P2 may be disposed over the pre-word line 13P.

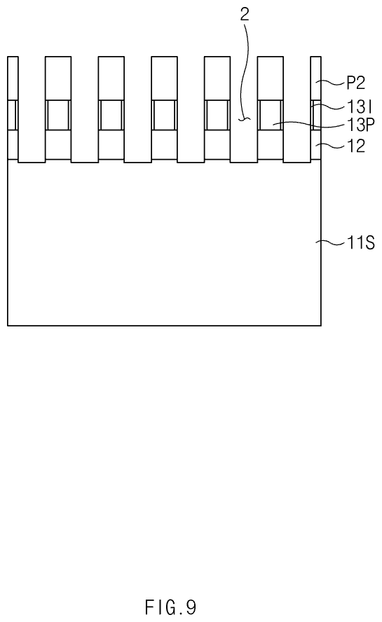

Referring to FIG. 9, the gate insulation layer 131 may be formed by oxidizing the pre-word line 13P exposed through the first openings 2.

As can be seen from FIG. 9, the first mask layer M1 may be removed.

The gate insulation layer 131 may be formed by oxidizing a sidewall of the pre-word line 13P containing polysilicon.

As an upper portion of the pre-word line 13P is overlapping with the second protective layer P2, a portion of the region corresponding to the sidewall of the pre-word line 13P may be selectively oxidized. Additionally, a portion of the upper substrate layer 11S exposed by the first opening 2 may be oxidized.

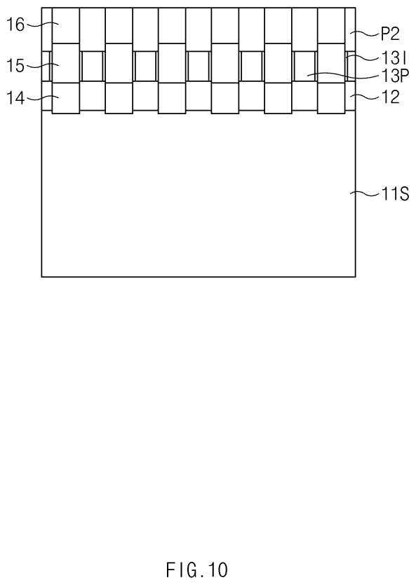

Referring to FIG. 10, the second region 14, the third region 15, and the fourth region 16 may be formed in the first opening 2 through an epitaxial process.

In some embodiments, before the second region 14, the third region 15, and the fourth region 16 are formed, a partial region of the oxidized upper substrate layer 11S may be removed.

The second region 14 may be an N-type impurity region. Additionally, the third region 15 may be a P-type impurity region, and the fourth region 16 may be an N-type impurity region.

The upper region of the fourth region 16 may contain a higher concentration of N-type impurities than the lower region of the fourth region 16. An impurity implantation process and an annealing (heat treatment) process may be performed to change the concentration of the upper region of the fourth region 16.

The semiconductor device according to some embodiments of the present disclosure may be formed by performing the epitaxial process on the second region 14, the third region 15, and the fourth region 16, so that the impurity concentrations of the second region 14, the third region 15, and the fourth region 16 can be easily controlled.

The impurity concentrations of the second region 14, the third region 15, and the fourth region 16 are controlled, so that the operating characteristics of the memory cell, such as leakage current or operating voltage, can be improved.

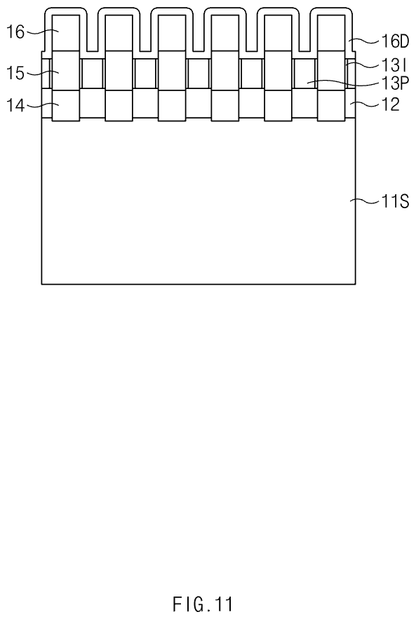

Referring to FIG. 11, the second protective layer P2 may be selectively removed so that a pre-capping layer 16D may be formed over the fourth region 16.

The second protective layer P2 may be selectively removed using etch selectivity to silicon nitride.

The pre-capping layer 16D may include an insulative material such as silicon oxide. The pre-capping layer 16D may allow the fourth region 16 and the pre-word line 13P to overlap with each other.

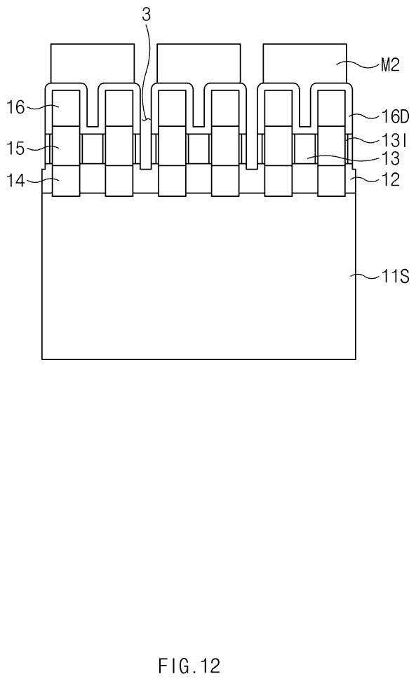

Referring to FIG. 12, a second mask layer M2 may be formed over the pre-capping layer 16D, and the pre-capping layer 16D and the pre-word line 13P may be selectively removed.

In the process of FIG. 12, adjacent pre-word lines 13P may be separated from each other to form the word lines 13.

Since at least one second opening 3 is formed using the second mask layer M2, adjacent pre-word lines 13P and the pre-capping layer 16D can be separated from each other. At least a portion of the second isolation layer 12 may be removed in the process of FIG. 12.

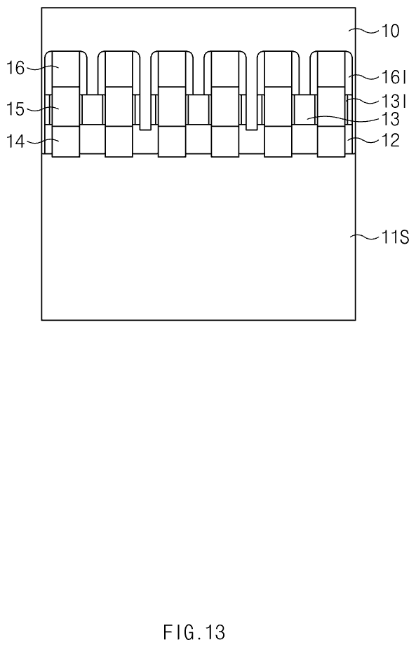

Referring to FIG. 13, the second mask layer M2 may be removed and the pre-capping layer 16D may be etched to form a capping layer 161. In addition, a first isolation layer 10 may be formed on the capping layer 161, the word line 13, and the fourth region 16.

The first isolation layer 10 may be a region containing silicon oxide. The first isolation layer 10 may be formed through silicon oxide deposition and CMP (Chemical Mechanical Planarization) processing.

In some embodiments, before forming the first isolation layer 10, metal silicide may be formed in a partial region of the word line 13 and a partial region of the fourth region 16.

Since metal silicide is formed as described above, contact resistance between the bit line contact and the fourth region 16 may be reduced.

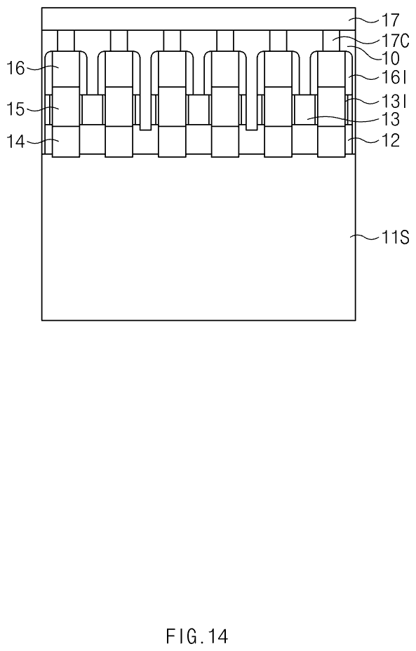

Referring to FIG. 14, a plurality of bit line contacts 17C connected to the fourth region 16 and a bit line 17 connected to the bit line contacts 17C may be formed.

Each of the bit line contacts 17C may be a vertical via containing a conductive material.

The bit line 17 may include a plurality of layers, and each layer may include metal, metal nitride, or metal silicide.

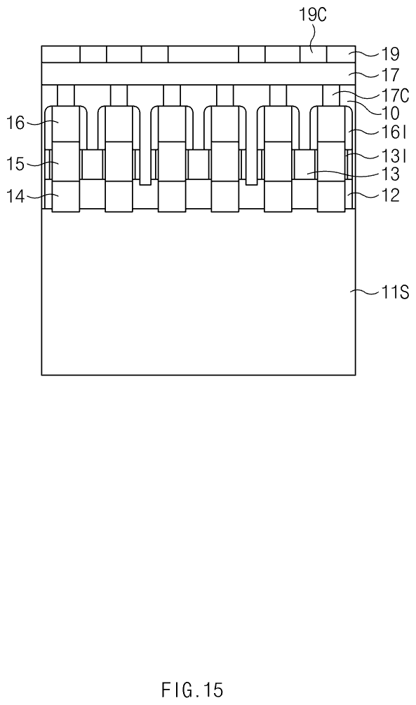

As shown in FIG. 15, a first bonding layer 19 may be formed on the bit line 17.

The first bonding layer 19 may include at least one first bonding pad 19C.

The first bonding layer 19 may include an insulative material, and each of the first bonding pads 19C may include a metal material.

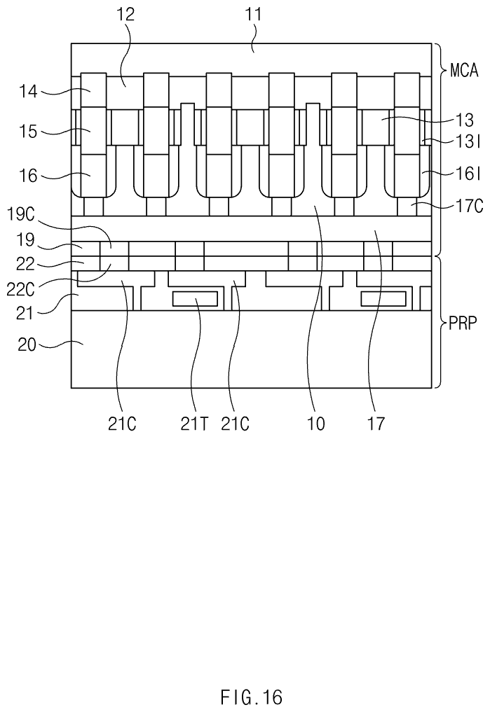

As shown in FIG. 16, the upper substrate layer 11S may be back-ground (or back-grinding processed).

The back-ground upper substrate layer 11S may be additionally doped with P-type impurities, and the region additionally doped with P-type impurities may be referred to as the first region 11.

The first region 11 may be formed through back grinding, P-type impurity doping, and annealing.

Additionally, the memory cell array (MCA) and the peripheral circuit region (PRP) may be connected through the first bonding layer 19 and the first bonding pad 19C.

As described above, the peripheral circuit region (PRP) may include a lower substrate layer 20, a third isolation layer 21, and a second bonding layer 22.

The lower substrate layer 20 may include silicon, monocrystalline silicon, polysilicon, amorphous silicon, silicon germanium, monocrystalline silicon germanium, polycrystalline silicon germanium, carbon doped silicon, or combinations thereof.

The third isolation layer 21 may include a first connection structure 21C and a control circuit 21T. The first connection structure 21C may include a multi-level metal interconnect. In addition, the control circuit 21T may include at least one transistor.

The second bonding layer 22 may include an insulative material and third bonding pads 22C spaced apart from each other. The third bonding pads 22C may include a metal material.

The memory cell array (MCA) and the peripheral circuit region (PRP) may be connected through the second bonding layer 22 and the third bonding pad 22C.

More specifically, the first bonding layer 19 and the second bonding layer 22 may be connected to each other, and the first bonding pad 19C and the third bonding pad 22C may be connected to each other.

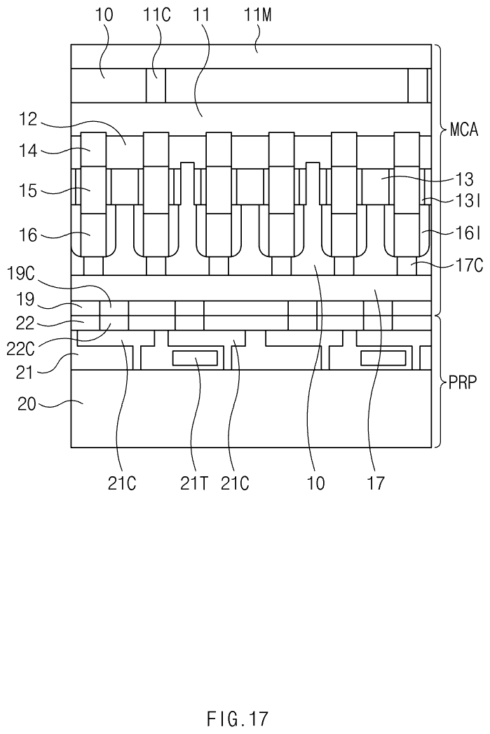

Referring to FIG. 17, an upper interconnect contact 11C and a first upper interconnect layer 11M may be formed over the first region 11.

The upper interconnect contact 11C may be a vertical via contact formed in the first isolation layer 10, and the first upper interconnect layer 11M may be a metal interconnect containing a conductive material.

As is apparent from the above description, the semiconductor device according to some embodiments of the present disclosure may include thyristors instead of capacitors.

The semiconductor device according to some embodiments of the present disclosure can implement a highly integrated memory device including vertical thyristors, and can simplify a fabrication process thereof.

The embodiments of the present disclosure may provide a variety of effects capable of being directly or indirectly recognized.

Those skilled in the art will appreciate that the embodiments of the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and/or enhancements to the disclosed embodiments and other embodiments can be devised based on what is described and/or illustrated in the present disclosure. Furthermore, the embodiments may be combined to form additional embodiments.

What is claimed is:

1. A semiconductor device comprising:
a bit line extending in a first direction;
a word line extending in a second direction perpendicular to the first direction; and
at least one thyristor contacting the bit line and extending in a third direction perpendicular to each of the first direction and the second direction,
wherein the thyristor includes
a first region;
a second region disposed below the first region;
a third region disposed below the second region; and
a fourth region disposed below the third region and connected to the bit line.

2. The semiconductor device according to claim 1, wherein:
the first region and the third region are regions containing impurities of a first conductivity type,
the second region and the fourth region are regions containing impurities of a second conductivity type, and
the word line surrounds at least a portion of the third region.

3. The semiconductor device according to claim 1, wherein
the word line includes polysilicon.

4. The semiconductor device according to claim 1, further comprising
a gate insulation layer disposed between the word line and the third region.

5. The semiconductor device according to claim 4, wherein
the gate insulation layer includes silicon oxide.

6. The semiconductor device according to claim 1, wherein
the first region is disposed over a second region included in a first thyristor and a second thyristor.

7. The semiconductor device according to claim 1 further comprising:
a plurality of thyristors arranged in a zigzag pattern with respect to the second direction and spaced apart from each other by a preset distance.

8. The semiconductor device according to claim 7, wherein:
the plurality of thyristors are arranged in two lines; and
the word line is formed to surround at least a portion of each of the plurality of thyristors.

9. The semiconductor device according to claim 1, wherein
the word line further includes a metal silicide.

10. The semiconductor device according to claim 1, wherein
the fourth region further includes a metal silicide.

11. A semiconductor device comprising:
a memory cell array; and
a peripheral circuit region disposed below the memory cell array,
wherein the memory cell array includes
a bit line extending in a first direction;
a word line extending in a second direction perpendicular to the first direction; and
at least one thyristor contacting the bit line and extending in a third direction perpendicular to each of the first direction and the second direction,
wherein the peripheral circuit region includes
a control circuit configured to provide a control signal to the memory cell array; and
a connection structure connected to the bit line.

12. The semiconductor device according to claim 11, wherein the thyristor includes:
a first region extending in the first direction;
a second region disposed below the first region;
a third region disposed below the second region; and
a fourth region disposed below the third region and connected to the bit line.

13. The semiconductor device according to claim 12, wherein:
the first region and the third region include impurities of a first conductivity type; and
the second region and the fourth region include impurities of a second conductivity type.

14. The semiconductor device according to claim 12, wherein
the word line is formed to surround the third region.

15. The semiconductor device according to claim 14, further comprising
a gate insulation layer disposed between the word line and the third region.

16. The semiconductor device according to claim 15, wherein:
the word line includes polysilicon; and
the gate insulation layer includes silicon oxide.

17. A method for manufacturing a semiconductor device the method comprising:
forming a conductive material layer over an upper substrate layer;
forming a pre-word line and at least one first opening by etching the conductive material layer; forming a gate insulation layer by oxidizing a portion of the pre-word line exposed through the first opening;
forming a second region, a third region, and a fourth region within the first opening through an epitaxial process;
forming a word line surrounding the third region by forming at least one second opening within the pre-word line;
forming a bit line connected to the fourth region; and
forming a first region by back-grinding the upper substrate layer and performing impurity doping on the back-ground upper substrate layer.

18. The method according to claim 17, further comprising:
forming a metal silicide layer within the word line; and
forming the metal silicide layer within the fourth region.

19. The method according to claim 17, further comprising:
forming a first bonding layer over the bit line;
forming a peripheral circuit region that includes a lower substrate layer and a second bonding layer; and
connecting the first bonding layer and the second bonding layer to each other.

20. A semiconductor device comprising:
at least two bit lines spaced apart from each other and extending parallel to each other in a first horizontal direction;
at least two thyristors, each thyristor extending vertically and being connected at a first end thereof to one of the at least two bit lines;
a word line extending in a second direction perpendicular to the first horizontal direction and surrounding a portion of a sidewall surface of the at least two thyristors;
wherein the at least two thyristors are aligned in a diagonal direction.
